(19) United States
(12) Patent Application Publication
(10) Pub. No.: US 2019/0244873 A1
(43) Pub. Date: Aug. 8, 2019

(54) FLEXIBLE GRAPHITE RIBBON HEAT SINK FOR THERMOELECTRIC DEVICE

(71) Applicants: Jason Davis, Commerce Township, MI (US); Artur Stepanove, Troy, MI (US); Eric Kozlowski, Oakland Township, MI (US); Magna Seating Inc, Aurora (CA)

(72) Inventors: Jason Davis, Commerce Township, MI (US); Artur Stepanove, Troy, MI (US); Eric Kozlowski, Oakland Township, MI (US)

(21) Appl. No.: 16/341,973

(22) PCT Filed: Oct. 12, 2017
(86) PCT No.: PCT/US2017/056242

§ 371 Date: Apr. 15, 2019

Related U.S. Application Data
(60) Provisional application No. 62/408,089, filed on Oct. 14, 2016.

(51) Int. Cl. H01L 23/373; F28F 21/02; F28F 3/02; H05K 7/20

(52) U.S. Cl. CPC H01L 23/373; H05K 7/20945; F28F 3/02; F28F 21/02

(57) ABSTRACT

A flexible heat sink with a flexible base having a first side configured to engage a heat generating component, and a second side opposite the first side. A plurality of fins extends from the second side of the base and each fin is made from a flexible graphite ribbon assembly. The plurality of fins may be a row of fins made from a single graphite ribbon assembly. Each fin may be configured with a u-shaped or triangular shaped channel. A flexible heat sink assembly may be configured with multiple flexible heat sinks sharing one common base. The heat sinks and rows of fins may be spaced apart in the heat sink assembly to create an array of fins enabling the heat sink assembly to flex lengthwise and widthwise across the base.

### CROSS-REFERENCE TO RELATED APPLICATIONS

This application claims priority based on U.S. provisional application No. 62/408,089 filed on Oct. 14, 2016, which is herein incorporated by reference.

### TECHNICAL FIELD

Example embodiments relate to a flexible graphite ribbon heat sink and heat sink assembly for an electronic component, such as a thermoelectric device and particularly a flexible thermoelectric device.

### BACKGROUND

Heat sinks operate passively to dissipate heat away from an electronic component or mechanical device. Heat sinks generally provide greater surface areas for transferring heat to a surrounding medium, such as air. Heat sinks may be used in combination with thermoelectric devices to create a temperature controller. Some applications may warrant the use of a flexible thermoelectric device and also a flexible heat sink. Applications for a flexible heat sink may include, for example, a cooling assembly, or a heating and cooling assembly for a vehicle seat.

### SUMMARY

According to one embodiment there is provided a flexible heat sink having a flexible base with a first side configured to engage a heat generating component, and a second side opposite the first side; and a plurality of fins, each fin extending from the second side of the base, and each fin comprising a flexible graphite ribbon assembly.

The flexible graphite ribbon assembly may consist of one or more layers of graphite ribbon extending between a top flexible substrate layer and a bottom flexible substrate layer. The one or more layers of graphite ribbon may be encased by the top flexible substrate layer and the bottom flexible substrate layer.

Each fin of the flexible heat sink may include first and second walls extending away from the second side of the base, each of the first and second walls having inner ends and outer ends, and a first panel parallel and adjacent to the base, the first panel connecting the inner end of the first wall to the inner end of the second wall.

Each of the first and second walls may extend parallel to each other, and the first and second walls and the first panel may define a u-shaped channel. Alternatively, each of the first and second walls may extend towards each other, and the first and second walls and the first panel may define a triangular shaped channel. In the latter embodiment, the outer ends of the first and second walls may be connected together and specifically, connected by an adhesive substance, an adhesive tape, or a heat staking connection.

The plurality of fins of the flexible heat sink may be a row of fins with the first walls and second walls of the fins extending in respective first and second planes, the row having one or more second panels parallel and adjacent to the base, each second panel situated in between and joining the first panels of two adjacent fins, the second panels spacing apart the fins and enabling the heat sink to flex lengthwise wise along the one row. The row of fins may be constructed from a single flexible graphite ribbon assembly.

For any of the flexible heat sinks described above, the at least one flexible substrate layer may be a polymer substrate layer, and specifically a polyimide or a polyethylene terephthalate (PET) layer. The flexible base may be a thermally conductive flexible tape or a pressure sensitive adhesive.

According to another embodiment there is provided a flexible heat sink assembly for a flexible thermoelectric module. The heat sink assembly includes two or more flexible heat sinks as described above. The first side of the base of each flexible heat sink is mounted to the flexible thermoelectric module and each flexible heat sink is spaced apart across a width of the flexible thermoelectric module, enabling the heat sink assembly to flex widthwise between the rows of fins.

In the flexible heat sink assembly, each flexible base of each heat sink may be a pressure sensitive adhesive. Alternatively, the flexible bases of the two or more flexible heat sinks are configured as one common base. In one embodiment, the common base is a thermally conductive flexible tape.

The flexible heat sink assembly may include two or more flexible heat sinks spaced apart in parallel, with the spaced apart flexible heat sinks and the rows of fins of the heat sinks creating a rectangular array of fins.

### BRIEF DESCRIPTION OF THE DRAWINGS

Advantages of the present invention will be readily appreciated as the same becomes better understood by reference to the following detailed description when considered in connection with the accompanying drawings wherein:

FIG. 1 is a front view of a heat sink assembly in accordance with one embodiment of the present disclosure;

FIG. 2 is a bottom view of the heat sink assembly;

FIG. 3 is a front perspective view of the heat sink assembly;

FIG. 4 is a bottom perspective view of the heat sink assembly;

FIG. 5 is a top perspective view of a graphite ribbon assembly for a heat sink in accordance with one embodiment of the present disclosure;

FIG. 6 is a perspective view of the graphite ribbon assembly of FIG. 5 configured with a plurality of fins;

FIG. 7 is a front view of the plurality of fins of FIG. 6; and

FIG. 8 is a side view of the heat sink assembly.

Like reference numerals are used throughout the Figures to denote similar elements and features.

### DETAILED DESCRIPTION OF EXAMPLE EMBODIMENTS

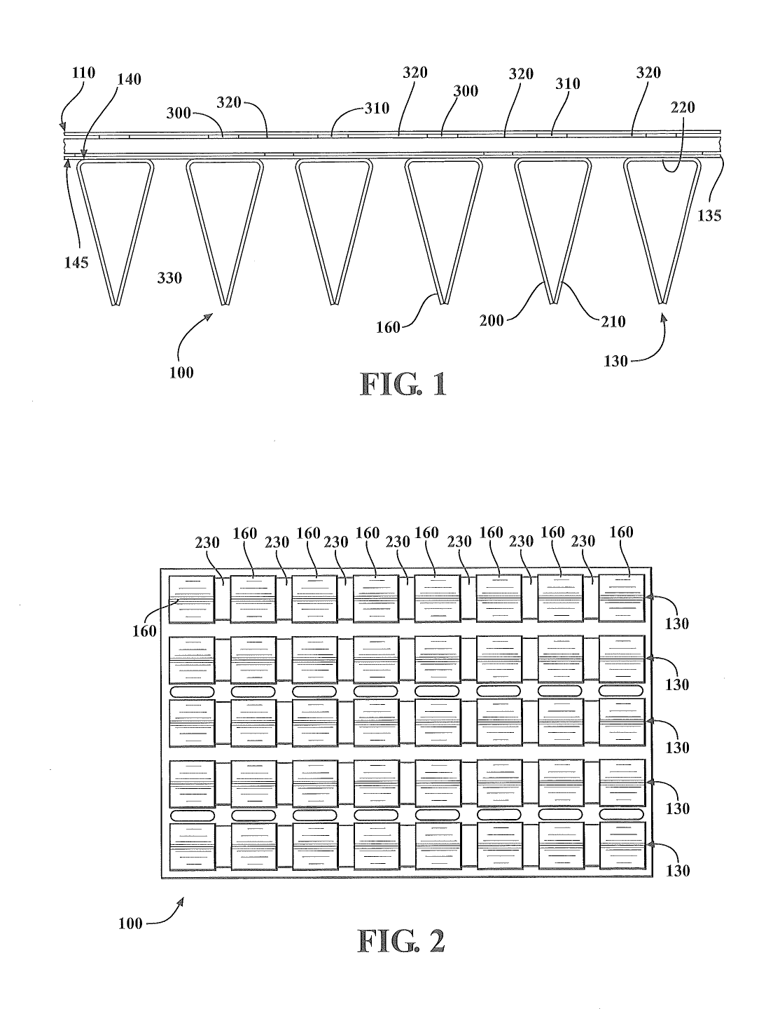

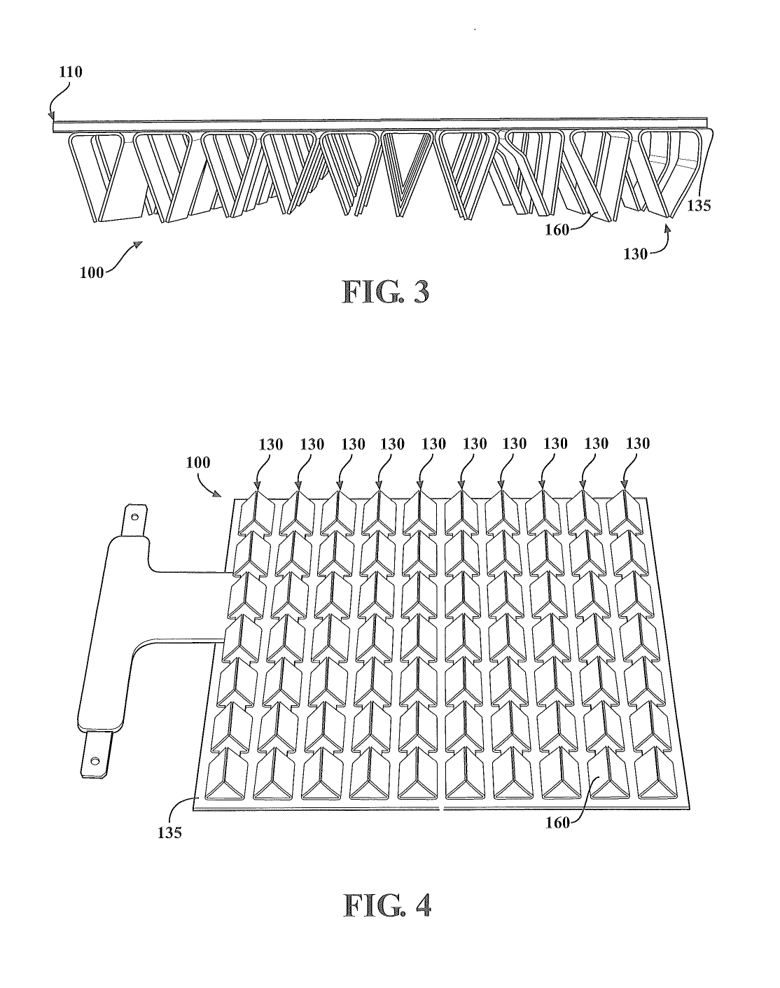

FIGS. 1 to 8 illustrate various heat sinks and heat sink assemblies according to embodiments described herein. Directional references employed in the specification or claims, such as top, bottom, upper, lower, upward, downward, lengthwise, widthwise, row, column, and the like, are employed for ease of description and are not intended to limit the scope of the invention in any respect. While many of the figures illustrate a heat sink with the fins extending towards the bottom of the figure, for example, it will be readily apparent that a heat sink according to the present disclosure may be oriented in any direction.

FIGS. 1 to 4 illustrate a flexible graphite ribbon heat sink assembly 100 according to one embodiment of the present disclosure. The heat sink assembly 100 may be used to cool a variety of electronic components or mechanical devices. As illustrated in FIG. 1, the heat sink assembly 100 may be attached or mounted to a flexible thermoelectric module 110. Together, the heat sink assembly 100 and thermoelectric module 110 may be used to create a temperature controller for use, for example, in a cooling apparatus, or heating and cooling apparatus, for a vehicle seat.

In one embodiment, the heat sink assembly 100 consists of multiple heat sinks 130 having a common, flexible base 135. In other embodiments, the heat sink assembly 100 consists of multiple heat sinks 130 with each heat sink 130 having its own base 135. The base 135 has a first side 140 which engages the device or component being cooled. The base 135 has a second side 145 opposite the first side 140. The second side 145 supports a plurality of heat sink fins 160. The fins 160 are walls or panels, as described below, which extend away from the second side 145 of the base 135 and which operate to dissipate heat from the base 135 and thermoelectric module 110 to the surrounding environment.

The thermoelectric module 110 may be a flexible module made of various layers and substrates, such as polyimides, polyolefins, and silicone. Thus, the heat sink assembly 100 is also flexible in order to conform to and flex with the module 110. In one embodiment, the base 135 is a thermally conductive flexible layer made of silicone or acrylic based material. The base 135 is thermally conductive but not conductive for electricity. The first side 140 of the base 135 may have an adhesive layer sufficient to attach the heat sink assembly 100 to the thermoelectric module 110. The second side 145 also may include an adhesive layer for connecting or attaching the fins 160. In one embodiment, the base 135 is a 3M™ 8805 Series thermally conductive adhesive transfer tape. In another embodiment, the base 135 comprises pressure sensitive adhesive.

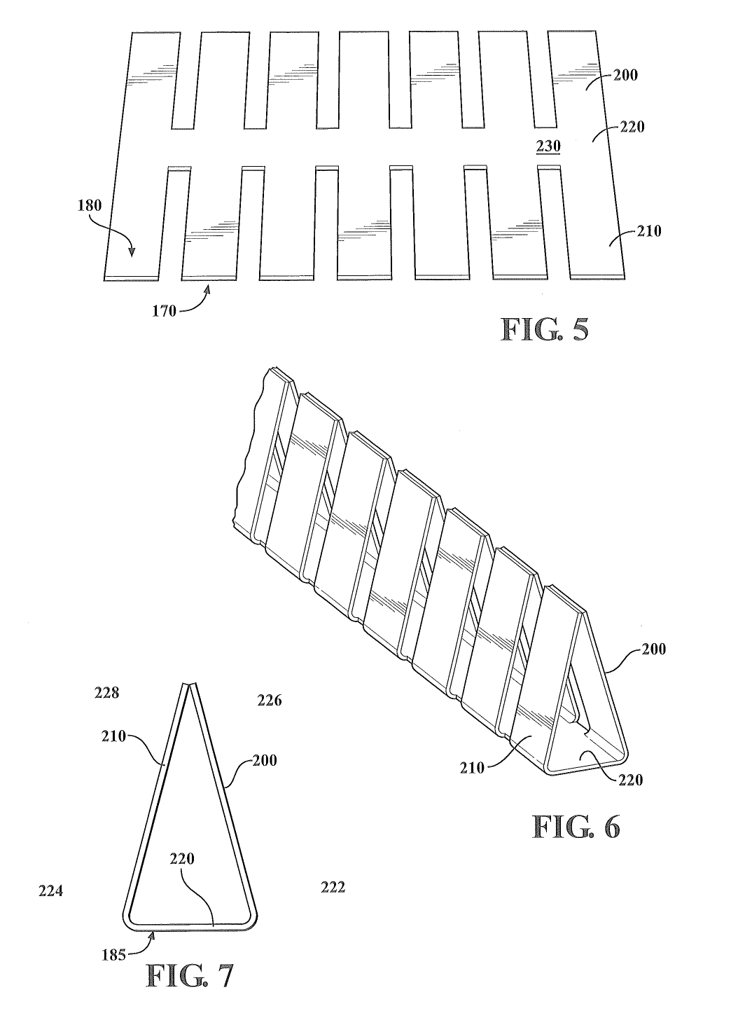

The heat sinks 130 and fins 160 are made of a thermally conductive graphite ribbon assembly 170, illustrated in FIGS. 5, 6 and 7. The graphite ribbon assembly 170 has one or more graphite ribbon layers mounted to or manufactured with a flexible substrate layer, such as a polymer substrate. In one embodiment, the graphite ribbon assembly 170 includes a top flexible substrate layer 180 and a bottom flexible substrate layer 185 with one or more graphite layers or ribbons extending between the top and bottom layers 180, 185. In one embodiment, the one or more graphite layers or ribbons are enclosed or encased by the top and bottom layers 180, 185. The polymer substrate layer may consist of a polyimide layer or tape such as Kapton™, or a polyethylene terephthalate (PET) layer or tape. The number of graphite layers or ribbons in the graphite ribbon assembly 170 may be varied depending on the requirements of the device, component or application for which the heat sinks 130 are used. In one embodiment, one graphite layer or ribbon is sufficient but more layers may be used depending on the amount of heat to be pulled away from the heat source to the fins 160. The height, width and spacing of the heat sinks 130 and fins 160 also may be varied depending on these requirements.

In one embodiment, as shown in FIGS. 5, 6 and 7, each heat sink 130 may be formed from a single piece of graphite ribbon assembly 170. The graphite ribbon assembly 170 may be made with the layers described above and then sized and cut for a specific application with a specific number of fins 160 and spacing of fins 160. In other embodiments, the graphite layers and the top and bottom flexible substrate layers 180, 185 are sized and cut prior to assembling the graphite ribbon assembly 170 so that the graphite layers are encased by the top and bottom flexible substrate layers 180, 185.

The heat sink 130 and heat sink assembly 100 may be provided with different shapes and configurations of the fins 160. In the embodiment shown in the figures, each fin 160 includes a first wall 200, a second wall 210, and a first panel 220 which is parallel and adjacent to the base 135. Each wall 200, 210 extends away from the second side 145 of the base 135. Inner ends 222, 224 of the walls 200, 210 are adjacent the second side 145 of the base 135 and are connected by the first panel 220.

In one embodiment (not shown) the walls 200, 210 extend away from first panel 220 and the second side 145 of the base 135 and are parallel to each other. Thus, the fins 160 define a generally u-shaped channel. In another embodiment, as seen in the figures, the walls 200, 210 extend away from first panel 220 and the second side 145 of the base 135 and towards each other. In this embodiment, the fins 160 define a generally triangular-shaped channel. The walls 200, 210 may be configured in the generally triangular shape without being attached to each other. In some embodiments, outer ends 226,228 of the walls 200, 210 may be connected together such as with an adhesive tape, an adhesive substance, or a heat staking connection. It will be appreciated that the shape of the channel provided by each fin 160 may be altered in use as the heat sink 130 flexes with the flex of the component or device to which it is attached.

As shown in FIGS. 2, 4, 5 and 6, the heat sink 130 may be constructed from a single graphite ribbon assembly 170 with fins 160 being linked or connected by second panels 230. The configuration of the second panels 230 between the fins 160 allows for a one-piece construction for the row of fins 160 while enabling the heat sink 130 to flex between the fins 160. The second panels 230 also provide more surface area for contacting the heat source, such as the thermoelectric module 110, through the base 135 of the heat sink 130. Although the walls 200, 210 and first panels 220 have been described as discrete components or sections, it will be appreciated that the walls 200, 210 and first panels 220 may be constructed or configured from a single panel or section of the graphite ribbon assembly 170 and spaced apart by sections identified as the second panels 230.

As noted above, the heat sink assembly 100 may consist of multiple heat sinks 130 having a common, flexible base 135, or multiple heat sinks 130 with each heat sink 130 having its own base 135. The heat sinks 130 may be spaced apart across the common base 135, or the heat sink assemblies 100 may be spaced apart and mounted to the thermoelectric module 110. The rows of fins 160 and spacing of the heat sinks 130 may be configured to create a rectangular array of heat sink fins 160. The gaps between the rows of fins 160 of the heat sinks 130 enable flexing in a first direction or width-wise across the thermoelectric module 110 and the heat sink assembly 100. Spaces or gaps between the fins 160 in each heat sink 130 enable flexing in second direction or lengthwise across the thermoelectric module 110 and the heat sink assembly 100. The size of the heat sink assembly 100, the number of heat sinks 130, and the number of fins 160 in each heat sink 130, may be configured to achieve different levels of flex and heat dissipation depending on the application for which the heat sink assembly 100 is used.

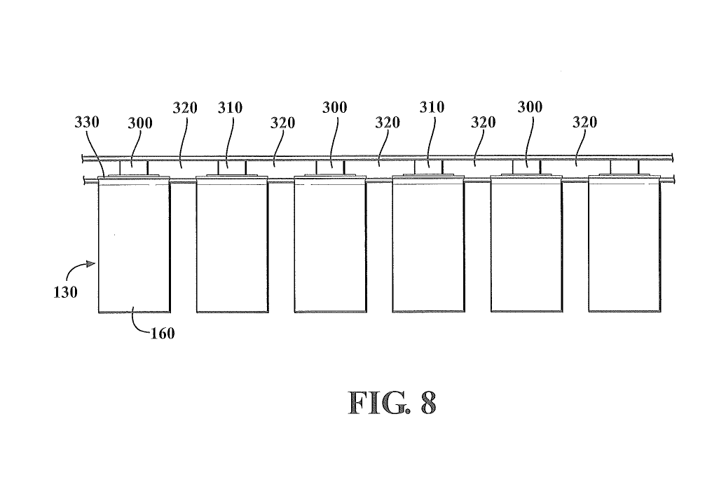

As also noted above, the flexible heat sink assembly 100 may be used and connected to a flexible thermoelectric module 110. In some embodiments, the heat sink assembly 100 is configured to match the flexing sections of the thermoelectric module 110 and also provide contact with as much surface area of the thermoelectric module 110 as possible. The fins 160 are arranged and spaced apart in order to be adjacent to the thermoelectric elements of the thermoelectric module 110. For example, FIG. 8 illustrates a side view of the heat sink assembly 100, and thus shows one heat sink 130. As seen in FIGS. 1 and 8, the heat sinks 130 are configured such that the fins 160 are adjacent to sections 300 of P-type thermoelectric materials and sections 310 of N-type thermoelectric materials in the thermoelectric module 110. The second panels 230 and spaces between the fins 160 are arranged adjacent sections 320 of isolator material in the thermoelectric module 110. The second panels 230 and spaces between the fins 160 also may correspond with spaces between bottom bus bars 330 of the thermoelectric module 110, thus enabling the heat sink assembly 100 to flex and match the flex of the thermoelectric module 110.

The one or more graphite ribbon layers of the graphite ribbon assembly 170 provide a heat sink 130 with a lower cost and mass compared to other materials for heat sink fins, such as copper or aluminum. High in-plane thermal conductivity of graphite ribbon compared to aluminum or copper enables the use of fewer fins to provide an equivalent cooling performance as compared to an aluminum or copper folded fin heat sink with a significantly greater number of fins. For example, FIG. 1 shows two fins 160 adjacent the bottom bus bar 330 of the thermoelectric module 110 whereas an aluminum or copper heat sink may require four to six fins across the same area to achieve the same performance. Fewer fins of the graphite ribbon assembly 170 also translates to a lower airflow restriction through the heat sinks 130 and heat sink assembly 100. This lower airflow restriction may mean a lower pressure drop across cooling system and thus less power may be required to move air through the system. As a result, the cost, mass and size of the blower or fan required to push or pull cooling air through the cooling system also may be lower.

The invention has been described in an illustrative manner, and it is to be understood that the terminology, which has been used, is intended to be in the nature of words of description rather than of limitation. Many modifications and variations of the present invention are possible in light of the above teachings. It is, therefore, to be understood that within the scope of the appended claims, the invention may be practiced other than as specifically described.

1. A flexible heat sink comprising:
a flexible base having a first side configured to engage a heat generating component, and a second side opposite the first side; and
a plurality of fins, each fin extending from the second side of the base, and each fin comprising a flexible graphite ribbon assembly.

2. The flexible heat sink of claim 1 wherein the flexible graphite ribbon assembly comprises one or more layers of graphite ribbon extending between a top flexible substrate layer and a bottom flexible substrate layer.

3. The flexible heat sink of claim 2 wherein the flexible graphite ribbon assembly comprise one layer of graphite ribbon extending between the top flexible substrate layer and the bottom flexible substrate layer.

4. The flexible heat sink of claim 2 or claim 3 wherein the flexible graphite ribbon assembly comprises the one or more layers of graphite ribbon being encased by the top flexible substrate layer and the bottom flexible substrate layer.

5. The flexible heat sink of any one of claims 1 to 4 wherein each fin comprises:
first and second walls extending away from the second side of the base, each of the first and second walls having inner ends and outer ends, and
a first panel parallel and adjacent to the base, the first panel connecting the inner end of the first wall to the inner end of the second wall.

6. The flexible heat sink of claim 5 wherein each of the first and second walls extends parallel to each other, and wherein the first and second walls and the first panel define a u-shaped channel.

7. The flexible heat sink of claim 5 wherein each of the first and second walls extends towards each other, and wherein the first and second walls and the first panel define a triangular shaped channel.

8. The flexible heat sink of claim 7 wherein the outer ends of the first and second walls are connected together.

9. The flexible heat sink of claim 8 wherein the outer ends of the first and second walls are connected by an adhesive substance, an adhesive tape, or a heat staking connection.

10. The flexible heat sink of any one of claims 5 to 9 wherein the plurality of fins comprises a row of fins with the first walls and second walls of the fins extending in respective first and second planes, the row comprising one or more second panels parallel and adjacent to the base, each second panel situated in between and joining the first panels of two adjacent fins, the second panels spacing apart the fins and enabling the heat sink to flex lengthwise wise along the one row.

11. The flexible heat sink of claim 10 wherein the row of fins is constructed from a single flexible graphite ribbon assembly.

12. The flexible heat sink of any one of claims 2 to 11 wherein the at least one flexible substrate layer comprises a polymer substrate layer.

13. The flexible heat sink of claim 12 wherein the polymer substrate layer comprises a polyimide or a polyethylene terephthalate (PET) layer.

14. The flexible heat sink of any one of claims 1 to 13 wherein the flexible base comprises a thermally conductive flexible tape.

15. The flexible heat sink of any one of claims 1 to 13 wherein the flexible base comprises a pressure sensitive adhesive.

16. A flexible heat sink assembly for a flexible thermoelectric module, the heat sink assembly comprising:
two or more flexible heat sinks according to any one of claims 10 to 13,
wherein the first side of the base of each flexible heat sink is mounted to the flexible thermoelectric module, and
wherein each flexible heat sink is spaced apart across a width of the flexible thermoelectric module, enabling the heat sink assembly to flex widthwise between the rows of fins.

17. The flexible heat sink assembly of claim 16 wherein each flexible base of each heat sink comprises a pressure sensitive adhesive.

18. The flexible heat sink assembly of claim 16 wherein the flexible bases of the two or more flexible heat sinks are configured as one common base.

19. The flexible heat sink assembly claim 18 wherein the common base comprises a thermally conductive flexible tape.

20. The flexible heat sink assembly of any one of claims 16 to 19 wherein the two or more flexible heat sinks are spaced apart in parallel, the spaced apart flexible heat sinks and the rows of fins of the heat sinks creating a rectangular array of fins.
